(19) United States
(12) Patent Application Publication
(10) Pub. No.: US 2015/0348895 A1
(43) Pub. Date: Dec. 3, 2015

(54) SUBSTRATE FOR SEMICONDUCTOR PACKAGING AND METHOD OF FORMING SAME

(71) Applicant: PBT PTE. LTD., Singapore (SG)

(72) Inventors: Amlan SEN, Singapore (SG); Shoa-Siong Raymond LIM, Singapore (SG)

(21) Appl. No.: 14/762,249

(22) PCT Filed: Jan. 21, 2014
(86) PCT No.: PCT/SG2014/000024

§ 371 Date: Jul. 21, 2015

Related U.S. Application Data
(60) Provisional application No. 61/754,671, filed on Jan. 21, 2013.

(51) Int. Cl. H01L 23/498; H01L 21/54; H05K 1/11; H01L 23/00; H01L 21/768; H05K 1/03; H01L 21/56; H01L 23/31

(52) U.S. Cl. CPC H01L 23/49827; H01L 21/56; H01L 21/54; H01L 23/3107; H01L 24/48; H01L 21/76898; H05K 1/0366; H05K 1/111; H01L 2224/48237; H05K 2201/0195

(57) ABSTRACT

A method of forming a substrate (10) for semiconductor packaging and a substrate (10) for semiconductor packaging are provided. The method includes providing a carrier (12) and forming a plurality of external pads (14) on the carrier (12), the external pads (14) formed on the carrier (12) defining a first conductive layer. A molding operation is performed to form a first insulating layer (20) on the carrier (12) with a molding compound (22). The first conductive layer is embedded in the first insulating layer (20). One or more of a plurality of bond pads (30), a plurality of conductive traces (32) and a plurality of microvias (56) are formed on the first conductive layer, the one or more of the bond pads (30), the conductive traces (32) and the microvias (56) formed on the first conductive layer defining a second conductive layer.

### FIELD OF THE INVENTION

The present invention relates to semiconductor packaging and more particularly to a substrate for semiconductor packaging, a method of forming the substrate, a semiconductor package formed with the substrate, and a method of packaging a semiconductor chip with the substrate.

### BACKGROUND OF THE INVENTION

Manufacturability is an important consideration in semiconductor packaging as it has a direct effect on packaging cost. Accordingly, to reduce packaging cost, it would be desirable to have a substrate that facilitates the semiconductor packaging process.

### SUMMARY OF THE INVENTION

Accordingly, in a first aspect, the present invention provides a method of forming a substrate for semiconductor packaging. The method includes providing a carrier and forming a plurality of external pads on the carrier, the external pads formed on the carrier defining a first conductive layer. A molding operation is performed to form a first insulating layer on the carrier with a molding compound. The first conductive layer is embedded in the first insulating layer. One or more of a plurality of bond pads, a plurality of conductive traces and a plurality of microvias are formed on the first conductive layer, the one or more of the bond pads, the conductive traces and the microvias formed on the first conductive layer defining a second conductive layer.

In a second aspect, the present invention provides a substrate for semiconductor packaging. The substrate includes a carrier and a plurality of external pads formed on the carrier, the external pads formed on the carrier defining a first conductive layer. A first insulating layer is formed on the carrier with a molding compound. The first conductive layer is embedded in the first insulating layer. One or more of a plurality of bond pads, a plurality of conductive traces and a plurality of microvias are formed on the first conductive layer, the one or more of the bond pads, the conductive traces and the microvias formed on the first conductive layer defining a second conductive layer.

In a third aspect, the present invention provides a method of packaging a semiconductor chip. The method includes providing a substrate for semiconductor packaging formed in accordance with the method of the first aspect, attaching the semiconductor chip to one of the external pads and a die pad of the substrate, electrically connecting the semiconductor chip to the bond pads of the substrate with a plurality of wires, encapsulating the semiconductor chip, the wires and the bond pads with an encapsulant, and removing the carrier to expose the first conductive layer.

In a fourth aspect, the present invention provides a semiconductor package including a plurality of external pads, the external pads defining a first conductive layer. The first conductive layer is embedded in a first insulating layer formed with a molding compound. One or more of a die pad, a plurality of bond pads, a plurality of conductive traces and a plurality of microvias are formed on the first conductive layer, the one or more of the die pad, the bond pads, the conductive traces and the microvias formed on the first conductive layer defining a second conductive layer. A semiconductor chip is attached to one of the external pads and the die pad and a plurality of wires electrically connects the semiconductor chip to the bond pads. An encapsulant encapsulates the semiconductor chip, the wires and the bond pads.

Other aspects and advantages of the invention will become apparent from the following detailed description, taken in conjunction with the accompanying drawings, illustrating by way of example the principles of the invention.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIGS. 1 through 4 are enlarged cross-sectional views illustrating a method of forming a substrate for semiconductor packaging in accordance with an embodiment of the present invention;

FIGS. 5 and 6 are enlarged cross-sectional views illustrating a method of packaging a semiconductor chip with the substrate of FIG. 4;

FIG. 7 is an enlarged cross-sectional view of a substrate for semiconductor packaging in accordance with another embodiment of the present invention;

FIG. 8 is an enlarged cross-sectional view of a semiconductor package formed with the substrate of FIG. 7;

FIGS. 9 and 10 are enlarged cross-sectional views illustrating a further embodiment of the method of forming the substrate for semiconductor packaging;

FIG. 11 is an enlarged cross-sectional view of a semiconductor package formed with the substrate of FIG. 10;

FIGS. 12 and 13 are enlarged cross-sectional views illustrating another further embodiment of the method of forming the substrate for semiconductor packaging;

FIG. 14 is an enlarged cross-sectional view of a semiconductor package formed with the substrate of FIG. 13;

FIGS. 15 through 21 are enlarged cross-sectional views illustrating a method of forming a substrate for semiconductor packaging in accordance with another embodiment of the present invention;

FIG. 22 is an enlarged cross-sectional view of a semiconductor package formed with the substrate of FIG. 21;

FIGS. 23 through 27 are enlarged cross-sectional views illustrating a method of forming a substrate for semiconductor packaging in accordance with yet another embodiment of the present invention;

FIG. 28 is an enlarged cross-sectional view of a semiconductor package formed with the substrate of FIG. 27;

FIGS. 29 through 31 are enlarged cross-sectional views illustrating a method of forming a substrate for semiconductor packaging in accordance with still another embodiment of the present invention;

FIG. 32 is an enlarged cross-sectional view of a substrate for semiconductor packaging in accordance with another embodiment of the present invention;

FIG. 33 is an enlarged cross-sectional view of a semiconductor package formed with the substrate of FIG. 31;

FIGS. 34 through 36 are enlarged cross-sectional views illustrating a method of forming a substrate for semiconductor packaging in accordance with yet another embodiment of the present invention;

FIG. 37 is an enlarged cross-sectional view of a semiconductor package formed with the substrate of FIG. 36;

FIG. 38 is an enlarged cross-sectional view of an external pad of a substrate for semiconductor packaging in accordance with a further embodiment of the present invention;

FIGS. 39 through 42 are enlarged cross-sectional views illustrating a method of forming a conductive film layer on an insulating layer in accordance with one embodiment of the present invention; and

FIGS. 43 and 44 are enlarged cross-sectional views illustrating a method of forming a conductive film layer on an insulating layer in accordance with another embodiment of the present invention.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the scope of the invention. In the drawings, like numerals are used to indicate like elements throughout.

FIGS. 1 through 4 are enlarged cross-sectional views illustrating a method of forming a substrate 10 for semiconductor packaging in accordance with an embodiment of the present invention.

Referring now to FIG. 1, a carrier 12 is provided and a plurality of external pads 14 is formed on the carrier 12, the external pads 14 formed on the carrier 12 defining a first conductive layer. In the embodiment shown, a first or bottom finishing layer 15 is formed on the carrier 12 prior to formation of the external pads 14. In an alternative embodiment, the bottom finishing layer 15 may be formed after removal of the carrier 12 on completion of the semiconductor packaging process.

The carrier 12 serves as a support for the other elements of the substrate 10 and may be made of any suitable material that is relatively rigid and electrically conductive. As examples, the carrier 12 may be made of a single metal layer, a multi-clad metal layer or a metal finishing coated layer. For example, the carrier 12 may be a steel or copper (Cu) plate. A plurality of recessed slots (not shown) may be pre-formed on the carrier 12.

In the embodiment shown, the first conductive layer is formed on the carrier 12 by forming a photoresist layer 16 on the carrier 12 and patterning the photoresist layer 16 to form a plurality of openings 18 in the photoresist layer 16. One or more metal layers are deposited in the openings 18 formed in the photoresist layer 16 to form the first conductive layer.

In one embodiment, the first conductive layer is formed by electroplating using the patterned photoresist layer 16 as a mask. A single metal layer such as, for example, copper (Cu) may be deposited in the openings 18. Alternatively, multiple metal layers such as, for example, gold (Au) and nickel (Ni), followed by copper (Cu) may be deposited in the openings 18.

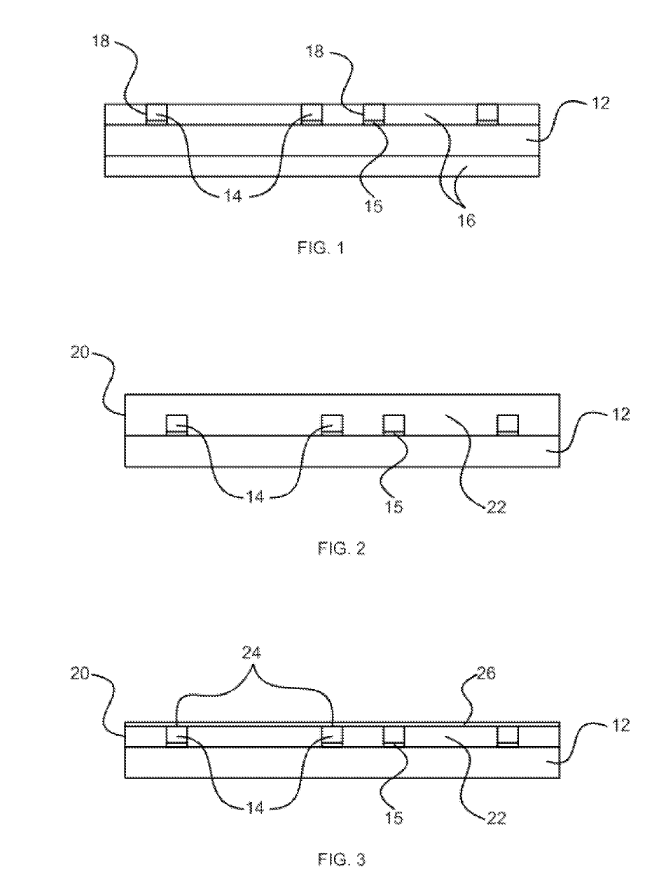

Referring now to FIG. 2, the photoresist layer 16 is removed and a molding operation is performed to form a first insulating layer 20 on the carrier 12 with a molding compound 22. As shown in FIG. 2, the first conductive layer is encapsulated by the first insulating layer 20 and is embedded in the first insulating layer 20. The first insulating layer 20 formed on the carrier 12 envelopes the first conductive layer.

The molding operation may be performed by an injection, transfer or a compression molding process. The molding compound 22 may be an epoxy resin compound.

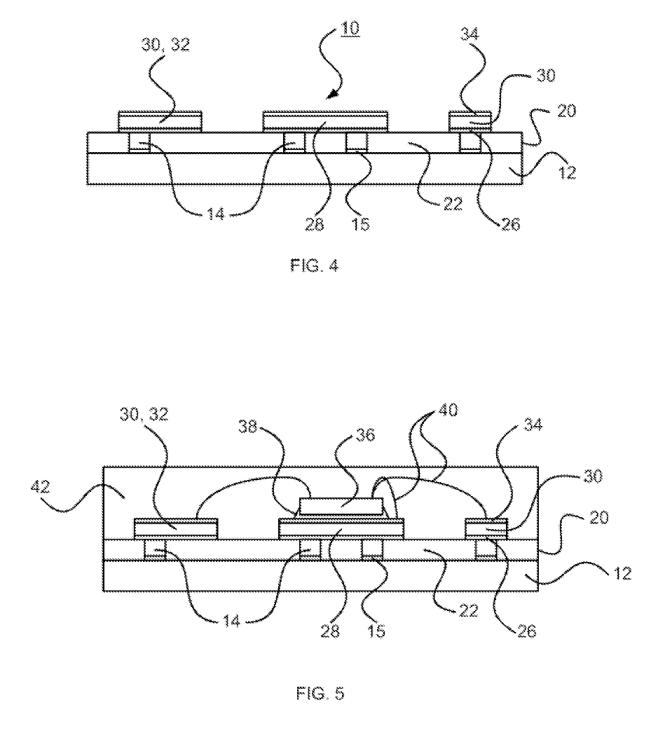

Referring now to FIG. 3, a portion of the first insulating layer 20 is removed after the molding operation to expose a surface 24 of the underlying conductive layer. A conductive film layer 26 is formed over the first insulating layer 20 and the first conductive layer. In the present embodiment, the conductive film layer 26 is a conductive seed layer.

The portion of the first insulating layer 20 may be removed by a mechanical grinding or a buffing process leaving a top surface of the first conductive layer completely exposed and substantially leveled with the top surface of the first insulating layer 20.

The conductive film layer 26 may be made of copper (Cu) and may be formed by an electroless process.

Referring now to FIG. 4, a die pad 28, a plurality of bond pads 30 and a plurality of conductive traces 32 are formed on the first conductive layer, the die pad 28, the bond pads 30 and the conductive traces 32 formed on the first conductive layer defining a second conductive layer. In the embodiment shown, a second or top finishing layer 34 is formed on the second conductive layer. The resultant substrate 10 may be used to package a semiconductor chip.

The second conductive layer is electrically connected to the first conductive layer. In the embodiment shown, the second conductive layer is formed on the first conductive layer and the first insulating layer 20, protruding above and overlapping the first insulating layer 20.

The second conductive layer may be formed on the first conductive layer using one of an additive or semi-additive method and a subtractive method.

In the additive or semi-additive method, a second photoresist layer (not shown) is formed over the conductive film layer 26 and subsequently patterned to expose the conductive film layer 26. The second conductive layer is then formed by electroplating using the patterned second photoresist layer as a mask. The second conductive layer may be formed of a single metal or multiple metal layers. In one embodiment, the second conductive layer is formed of copper (Cu). After the second conductive layer is formed, the patterned second photoresist layer is removed. Thereafter, exposed portions of the conductive film layer 26 are removed, for example, by chemical etching.

In the subtractive method, a metal layer is formed on the conductive film layer 26 by electroplating. The metal layer may be formed of a single metal or multiple metal layers. In one embodiment, the metal layer is formed of copper (Cu). A second photoresist layer (not shown) is then formed over the metal layer and patterned to expose the metal layer. Exposed portions of the metal layer and the conductive film layer 26 are removed to form the second conductive layer. This may be by chemical etching. Once this is done, the patterned second photoresist layer is removed.

The second finishing layer 34 may be formed on the second conductive layer by electroplating with one or more of nickel (Ni), palladium (Pd) and gold (Au).

As will be appreciated by those of ordinary skill in the art, FIGS. 1 through 4 illustrate one embodiment of the method of forming the substrate 10 for semiconductor packaging. Other embodiments are described below. As shown in FIG. 4, the substrate 10 thus formed includes a carrier 12. A plurality of external pads 14 is formed on the carrier 12, the external pads 14 formed on the carrier 12 defining a first conductive layer. A first insulating layer 20 is formed on the carrier 12 with a molding compound 22. The first conductive layer is embedded in the first insulating layer 20. A die pad 28, a plurality of bond pads 30 and a plurality of conductive traces 32 are formed on the first conductive layer and define a second conductive layer. A conductive film layer 26 is formed over the first conductive layer and at least partially over the first insulating layer 20. In the embodiment shown, the conductive film layer 26 interfaces between the first and second conductive layers and between portions of the first insulating layer 20 and the second conductive layer. In the present embodiment, the substrate 10 also includes a first or bottom finishing layer 15 interfacing between the carrier 12 and the first conductive layer and a second or top finishing layer 34 formed on a top surface of the second conductive layer.

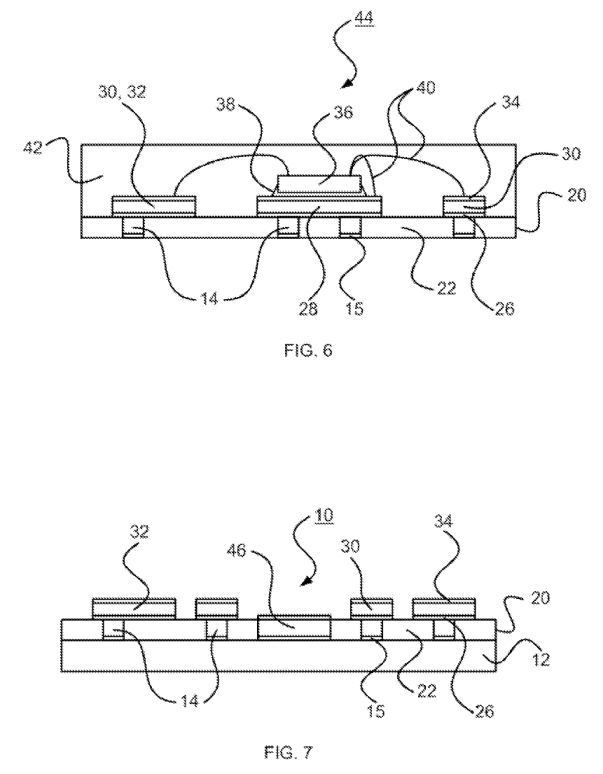

Having described the method of forming the substrate 10 for semiconductor packaging, a method of packaging a semiconductor chip 36 with the substrate 10 will now be described below with reference to FIGS. 5 and 6.

Referring now to FIG. 5, the substrate 10 of FIG. 4 is provided as shown and the semiconductor chip 36 is attached to the die pad 28 of the substrate 10 with an adhesive 38. The semiconductor chip 36 is then electrically connected to the bond pads 30 of the substrate 10 with a plurality of wires 40. Thereafter, the semiconductor chip 36, the wires 40 and the bond pads 30 of the substrate 10 are encapsulated with an encapsulant 42.

The semiconductor chip 36 may be any type of circuit such as, for example, a digital signal processor (DSP) or a special function circuit, and is not limited to a particular technology such as complementary metal-oxide-semiconductor (CMOS), or derived from any particular wafer technology. The semiconductor chip 36 has an active surface on one side and a non-active surface on an opposite side. The active surface of the semiconductor chip 36 faces away from the die pad 28 and includes a plurality of input and output (I/O) pads (not shown). The non-active surface of the semiconductor chip 36 is attached to the adhesive 38.

In one embodiment, the adhesive 38 may be a die attach epoxy that is dispensed within a die attach pad area of the substrate 10 before die placement and curing.

The wires 40 electrically connect the input and output (I/O) pads on the semiconductor chip 36 to the corresponding bond pads 30, thereby bonding the semiconductor chip 36 to the bond pads 30. The wires 40 may be made of gold (Au), copper (Cu) or other electrically conductive materials as are known in the art and commercially available.

The encapsulant 42 forms a second insulating layer over the substrate 10 and encapsulates the pad layer 28, the lead layer 30 and 32, the semiconductor die 36, the epoxy 38 and the electrical connectors 40. The dielectric layer 42 may be formed on the substrate 10 by compression, transfer or injection molding. The encapsulant 42 may comprise well-known commercially available molding materials such as an epoxy molding compound.

Referring now to FIG. 6, the carrier 12 of the substrate 10 is removed to expose the first conductive layer. In the present embodiment, the bottom surfaces of the leads and the die attach pad are exposed when the carrier 12 is removed. The carrier 12 may be removed by an etching process or a wet etching process.

As a result of the molding operation used to form the first insulating layer 20, the molding compound 22 is packed against the sides of the external pads 14, preventing seepage of wet chemicals at the interface between the molding compound 22 and the external pads 14. Advantageously, this helps prevent the edges of the external pads 14 from being eaten away by the wet chemicals and this in turn helps maintain the outer dimensions of the external pads 14.

As can be seen from FIG. 6, the semiconductor package 44 thus formed includes a plurality of external pads 14 defining a first conductive layer and a first insulating layer 20 formed with a molding compound 22. The first conductive layer is embedded in the first insulating layer 20. A conductive film layer 26 is formed over the first conductive layer and at least partially over the first insulating layer 20. A die pad 28, a plurality of bond pads 30 and a plurality of conductive traces 32 are formed on the first conductive layer and define a second conductive layer. A semiconductor chip 36 is attached to the die pad 28 and a plurality of wires 40 electrically connects the semiconductor chip 36 to the bond pads 30. An encapsulant 42 encapsulates the semiconductor chip 36, the wires 40 and the bond pads 30.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

Although a single package unit is illustrated in FIGS. 1 through 6, it should be understood that the substrate 10 is not limited to single package processing and may be used to form a plurality of semiconductor packages 44 simultaneously. In such embodiments, the assembled frame may be singulated to form individual packages.

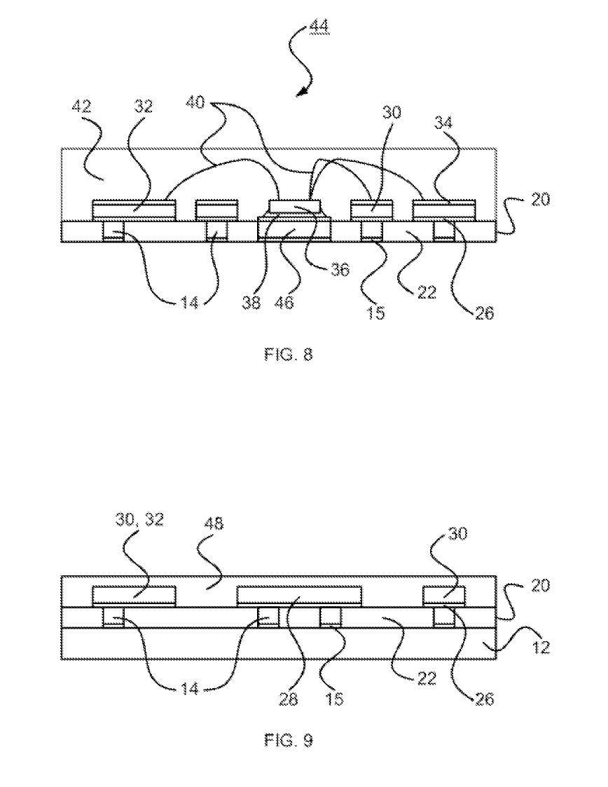

Referring now to FIG. 7, an enlarged cross-sectional view of a substrate 10 for semiconductor packaging in accordance with another embodiment of the present invention is shown. The substrate 10 includes a carrier 12 and an external die pad 46 and a plurality of external pads 14 formed on the carrier 12. The external die pad 46 and the external pads 14 formed on the carrier 12 define a first conductive layer. A first insulating layer 20 is formed on the carrier 12 with a molding compound 22. The first conductive layer is embedded in the first insulating layer 20. A plurality of bond pads 30 and a plurality of conductive traces 32 are formed on the first conductive layer. The bond pads 30 and the conductive traces 32 formed on the first conductive layer define a second conductive layer.

The substrate 10 of FIG. 7 differs structurally from that of the preceding embodiment in that the substrate 10 of FIG. 7 is formed with a die pad ring.

Referring now to FIG. 8, an enlarged cross-sectional view of a semiconductor package 44 formed with the substrate 10 of FIG. 7 is shown. The semiconductor package 44 includes an external die pad 46 and a plurality of external pads 14, the external die pad 46 and the external pads 14 defining a first conductive layer. The semiconductor package 44 also includes a first insulating layer 20 formed with a molding compound 22. The first conductive layer is embedded in the first insulating layer 20. A plurality of bond pads 30 and a plurality of conductive traces 32 are formed on the first conductive layer, the bond pads 30 and the conductive traces 32 formed on the first conductive layer defining a second conductive layer. A semiconductor chip 36 is attached to the external die pad 46 and a plurality of wires 40 electrically connects the semiconductor chip 36 to the bond pads 30. An encapsulant 42 encapsulates the semiconductor chip 36, the wires 40 and the bond pads 30.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

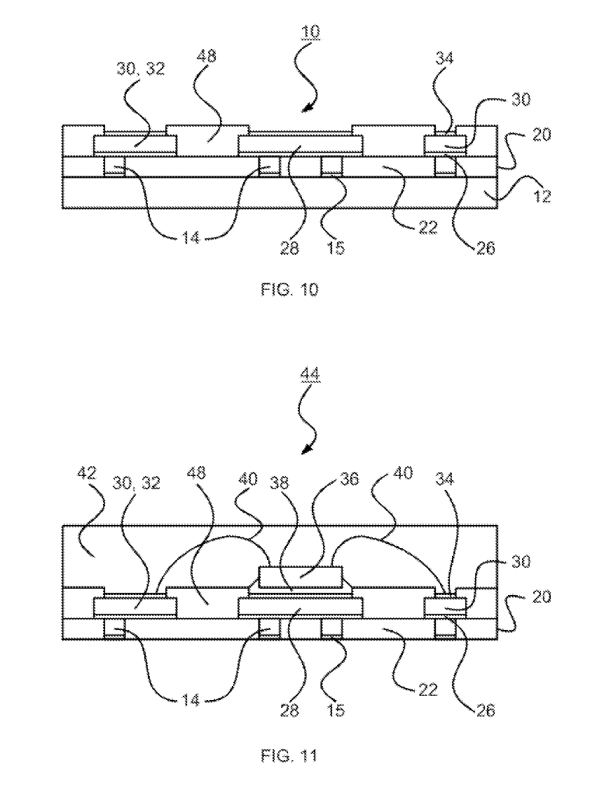

Following, in part, from FIG. 4 and with further reference to FIGS. 9 and 10, a further embodiment of the method of forming the substrate 10 for semiconductor packaging will now be described below.

Referring now FIG. 9, a second or successive insulating layer 48 is formed over the first insulating layer 20 after exposed portions of the conductive film layer 26 are removed. In the present embodiment, the second insulating layer 48 encapsulates the second conductive layer and is formed of a solder mask material, for example, an epoxy solder mask material. In the present embodiment, the conductive film layer 26 is a conductive seed layer.

Referring now to FIG. 10, the second insulating layer 48 is patterned to expose portions of the second conductive layer and a second or top finishing layer 34 is formed on the exposed portions of the second conductive layer.

The substrate 10 thus formed further includes a second insulating layer 48 made of a solder mask material formed over the first insulating layer 20 and a top finishing layer 34 on the exposed portions of the second conductive layer. As shown in FIG. 10, the second insulating layer 48 envelopes the second conductive layer and overlies a portion of the top surface of the second conductive layer.

Referring now to FIG. 11, a semiconductor package 44 formed with the substrate 10 of FIG. 10 is shown. The semiconductor package 44 includes a plurality of external pads 14 defining a first conductive layer. The first conductive layer is embedded in a first insulating layer 20 formed with a molding compound 22. A conductive film layer 26 is formed over the first conductive layer and at least partially over the first insulating layer 20. A die pad 28, a plurality of bond pads 30 and a plurality of conductive traces 32 are formed on the first conductive layer and define a second conductive layer. A second insulating layer 48 made of a solder mask material is formed over the first insulating layer 20 and a top finishing layer 34 is formed on portions of the second conductive layer. A semiconductor chip 36 is attached to the die pad 28 and a plurality of wires 40 electrically connects the semiconductor chip 36 to the bond pads 30. An encapsulant 42 encapsulates the semiconductor chip 36, the wires 40, the bond pads 30 and a surface of the second insulating layer 48.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

Advantageously, the masking layer 48 covers the exposed traces 32, masking out any unrequired traces 32 and strengthening the adhesion of the traces 32 to the molding compound 22.

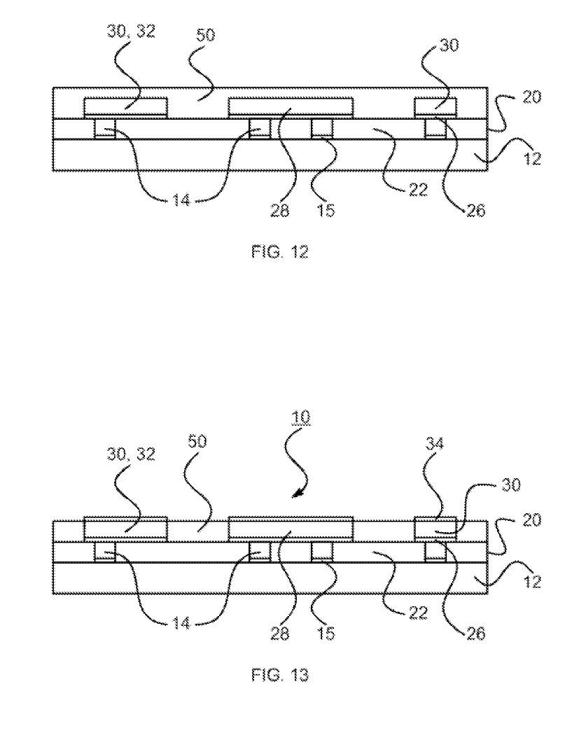

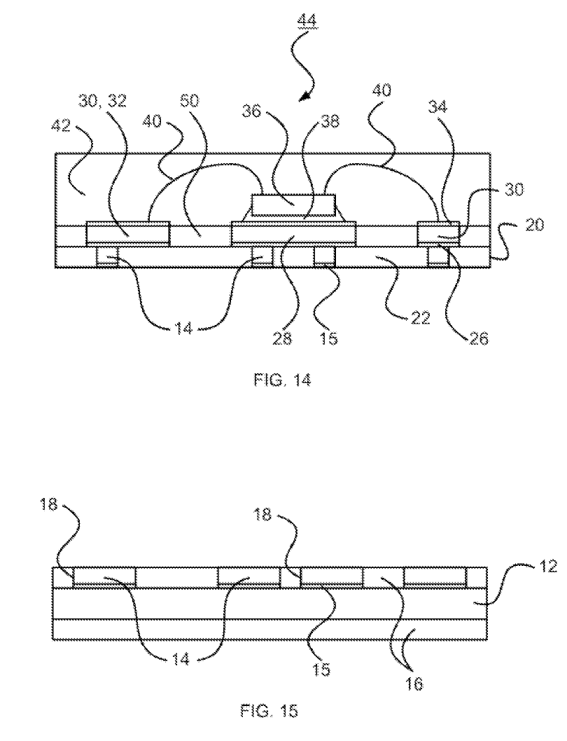

Following, in part, from FIG. 4 and with further reference to FIGS. 12 and 13, another further embodiment of the method of forming the substrate 10 for semiconductor packaging will now be described below.

Referring now to FIG. 12, a second or successive insulating layer 50 is formed over the first insulating layer 20 after exposed portions of the conductive film layer 26 are removed. In the present embodiment, the second insulating layer 50 encapsulates the second conductive layer and is formed of a molding compound material such as, for example, an epoxy resin compound. The molding compound material may be similar to that used to form the first insulating layer 20. The second insulating layer 50 may be formed by an injection or a compression molding process. In the present embodiment, the conductive film layer 26 is a conductive seed layer.

Referring now to FIG. 13, a portion of the second insulating layer 50 is removed to expose a surface of the second conductive layer and a second or top finishing layer 34 is formed on the exposed surface of the second conductive layer. The portion of the second insulating layer 50 may be removed by a mechanical grinding or a buffing process.

The substrate 10 thus formed further includes a second insulating layer 50 made of a molding compound material formed over the first insulating layer 20 and a top finishing layer 34 on the exposed surface of the second conductive layer. As shown in FIG. 13, a top surface of the second conductive layer is completely exposed and is substantially levelled with a top surface of the second insulating layer 50.

Referring now to FIG. 14, a semiconductor package 44 formed with the substrate 10 of FIG. 13 is shown. The semiconductor package 44 includes a plurality of external pads 14 defining a first conductive layer. The first conductive layer is embedded in a first insulating layer 20 formed with a molding compound 22. A conductive film layer 26 is formed over the first conductive layer and at least partially over the first insulating layer 20. A die pad 28, a plurality of bond pads 30 and a plurality of conductive traces 32 are formed on the first conductive layer and define a second conductive layer. A second insulating layer 50 made of a molding compound material is formed over the first insulating layer 20 and a top finishing layer 34 is formed on a surface of the second conductive layer. A semiconductor chip 36 is attached to the die pad 28 and a plurality of wires 40 electrically connects the semiconductor chip 36 to the bond pads 30. An encapsulant 42 encapsulates the semiconductor chip 36, the wires 40, the bond pads 30 and a surface of the second insulating layer 50.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

FIGS. 15 through 21 are enlarged cross-sectional views illustrating a method of forming a substrate for semiconductor packaging in accordance with another embodiment of the present invention.

Referring now to FIG. 15, a carrier 12 is provided and a plurality of external pads 14 is formed on the carrier 12, the external pads 14 formed on the carrier 12 defining a first conductive layer. The carrier may be a steel or copper plate. In the embodiment shown, a first or bottom finishing layer 15 is formed on the carrier 12 prior to formation of the external pads 14. In an alternative embodiment, the first or bottom finishing layer 15 may be formed after removal of the carrier 12 on completion of the semiconductor packaging process.

In the embodiment shown, the first conductive layer is formed on the carrier 12 by forming a first photoresist layer 16 on the carrier 12 and patterning the first photoresist layer 16 to form a plurality of openings 18 in the first photoresist layer 16. One or more metal layers are deposited in the openings 18 formed in the first photoresist layer 16 to form the first conductive layer.

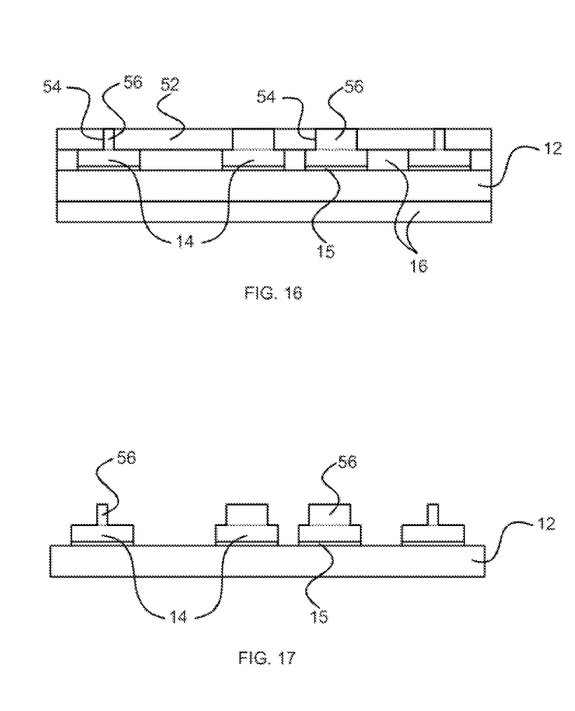

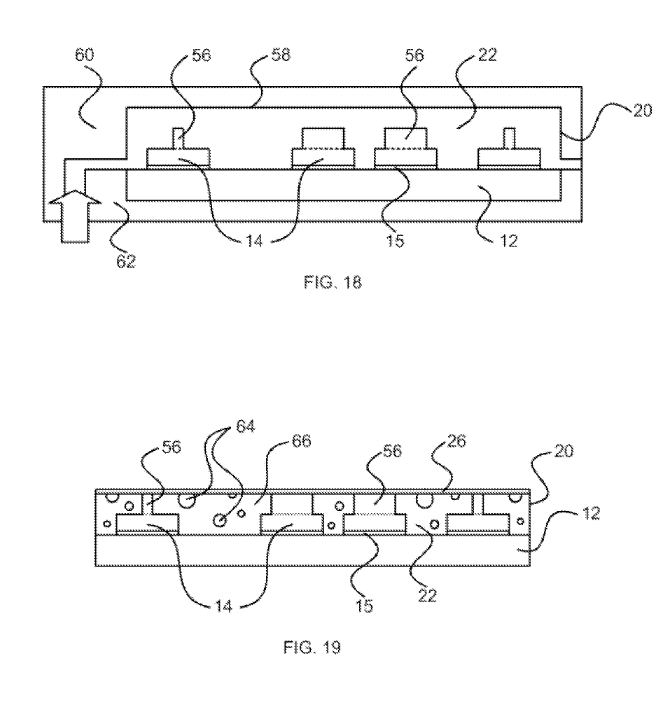

Referring now to FIG. 16, a second photoresist layer 52 is formed on the first conductive layer and the first photoresist layer 16. The second photoresist layer 52 is then patterned to form a plurality of microvia holes 54 extending through the second photoresist layer 52 and exposing portions of a top surface of the first conductive layer. A plurality of microvias 56 is formed on the external pads 14 by electroplating a single metal such as, for example, copper (Cu) or multiple metal layers such as, for example, combinations of copper (Cu), nickel (Ni), palladium (Pd) and gold (Au) on the first conductive layer using the patterned second photoresist layer 52 as a mask. In the present embodiment, the plurality of microvias 56 defines a second conductive layer. As can be seen from FIG. 16, each of the microvias 56 has a diameter that is smaller than a width or diameter of a corresponding external pad 14.

Referring now to FIG. 17, the first and second photoresist layers 16 and 52 are removed after the microvias 56 are formed on the external pads 14. The microvias 56 are thus formed on the external pads 14 prior to performing a molding operation to form the first insulating layer 20 on the carrier 12.

Referring now to FIG. 18, a molding operation is performed to form a first insulating layer 20 on the carrier 12 with a molding compound 22. As shown in FIG. 18, both the first and second conductive layers are encapsulated by the first insulating layer 20 and the microvias 56 are embedded in the first insulating layer 20 after the molding operation.

In the embodiment shown, the molding operation involves placing the carrier 12 with the first conductive layer formed thereon in a mold cavity 58 defined by a first mold part 60 and a second mold part 62. The mold cavity 58 is packed with the molding compound 22 in a liquid state by injection. The molding compound 22 is injected into the mold cavity 58 in a liquid or molten state at high temperature and high pressure to fill the mold cavity 58 completely. The molding compound 22 is subsequently cured and solidifies to form the first insulating layer 20 on the carrier 12.

The molding compound 22 is preferably a polymeric thermoset material. Alternatively, a polymeric thermoplastic material may also be used. In the present embodiment, the molding compound 22 includes a polymer resin and one or more types of fillers. The one or more types of fillers are distributed across the volume of the resin matrix. The resin may be epoxy-based or acrylic-based and the one or more types of fillers may be silica, ceramic and/or glass fillers. In one embodiment, the molding compound 22 includes between about 70 weight percent and about 95 weight percent of the one or more fillers. In the same or a different embodiment, the molding compound 22 has a coefficient of thermal expansion of between about 5 and about 15 parts per million per degree Celsius (ppm/° C.).

Although an injection molding process is shown in FIG. 18, it should be understood by those of ordinary skill in the art that the present invention is not limited by the type of molding process employed. For example, in an alternative embodiment, the first insulating layer 20 may be formed by a compression molding process.

Advantageously, use of a molding operation to form the body of the substrate 10 allows encapsulation of microvias 56 with high aspect ratios, for example, an aspect ratio of greater than one (1), without damaging the slender structure of the microvias 56. The molding compound 22, in liquid or molten state, conforms easily to the high aspect ratio features formed on the carrier 22. The mold cavity 58 confines the liquid molding compound 22 within the desired area to be encapsulated. The molding compound 22 cures and solidifies to form the first insulating layer 20 before removing the carrier 12 with the first insulating layer 20 from the mold tooling.

Referring now to FIG. 19, a portion of the first insulating layer 20 is removed after the molding operation to expose a surface of an underlying conductive layer, in this embodiment, the second conductive layer. A conductive film layer 26 is formed over the first insulating layer 20 and the second conductive layer prior to forming a die pad, a plurality of bond pads and a plurality of conductive traces over the second conductive layer.

The portion of the first insulating layer 20 may be removed after the molding operation by a mechanical grinding or a buffing process. Advantageously, this evens out the height of the microvias 56 and creates a leveled plane with the surface of the first insulating layer 20 for subsequent processes. In this embodiment, the thickness of the insulating layer 20 is equal to the aggregated height of the external pads 14 and the microvias 56.

Due to the nature of the molding process, the one or more types of fillers 64 tend to remain within the resin matrix with minimal exposure on the surface of the first insulating layer 20 immediately after the molding operation and the surface of the first insulating layer 20 immediately after the molding operation is mainly resin 66. The characteristic of the surface of the first insulating layer 20 is however altered when the surface of the first insulating layer 20 is leveled with the surface of the second conductive layer. After removal of a portion of the first insulating layer 20 by a mechanical grinding or a buffing process after the molding operation, the one or more types of fillers 64 become exposed on the surface of the first insulating layer 20 and the surface of the first insulating layer 20 then includes areas of filler interspersed amongst areas of resin. This is advantageous as the exposed filler surfaces provide better adhesion than the resin surfaces. The ratio of the filler surface area to the resin surface area is dependent on the filler content of the molding compound 22. For a molding compound 22 with a filler content of between about 70 percent (%) and about 95 percent (%), the filler surface area exposed on the surface of the first insulating layer 20 is between about 50% and about 80% with the remaining portion being resin surface area.

The conductive film layer 26 may be formed by an electroless deposition process and may be made of copper (Cu) or nickel (Ni). Prior to depositing the conductive film layer 26, the surface of the first insulating layer 20 and the surface of the second conductive layer may be chemical treated to improve adhesion to the conductive film layer 26. This may be by one or both of roughening a surface of the first insulating layer 20 and/or the second conductive layer (for the one or more fillers 64 and the first conductive layer) prior to forming the conductive film layer 26 and chemically activating a plurality of surface bonds of the first insulating layer 20 (for resin 66) prior to forming the conductive film layer 26. Different chemical solutions may be used to treat the filler surface, the resin surface and the surface of the second conductive layer. The conductive film layer 26 adheres to the filler surface, the resin surface and the surface of the second conductive layer after deposition. Comparatively, the conductive film layer 26 adheres very well to the filler surface and the surface of the second conductive layer, but does not adhere well to the resin surface. Due to the high filler content of the molding compound 22, the conductive film layer 26 bonds mostly with the filler surface and thus strong adhesion is achieved between the conductive film layer 26 and the first insulating layer 20.

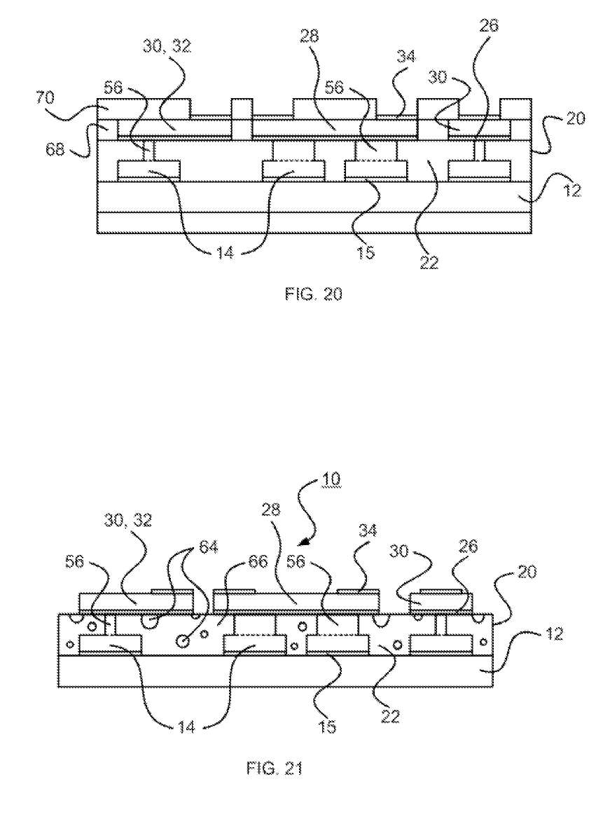

Referring now to FIG. 20, a die pad 28, a plurality of bond pads 30 and a plurality of first conductive traces 32 are formed on the second conductive layer and define a third conductive layer. As can be seen from FIG. 20, the microvias 56 electrically connect the external pads 14 to the third conductive layer. In the present embodiment, a second or top finishing layer 34 is formed on exposed surfaces of the third conductive layer. In alternative embodiments, more than one (1) die pad 28 may be formed.

The third conductive layer may be formed by forming a third photoresist layer 68 on the conductive film layer 26 and patterning the third photoresist layer 68 to expose the conductive film layer 26. The third conductive layer may then be formed on the conductive film layer 26 by an electroplating deposition process using the patterned third photoresist layer 68 as a mask. The third conductive layer may be formed of a single metal such as, for example, copper (Cu) or multiple metal layers such as, for example, combinations of copper (Cu), nickel (Ni), palladium (Pd) and gold (Au).

The second or top finishing layer 34 may be formed on the third conductive layer by forming a fourth photoresist layer 70 and patterning the fourth photoresist layer 70 to expose selected portions of the third conductor layer. The second or top finishing layer 34 may then be formed on the third conductive layer by electroplating with one or more of metal layers of nickel (Ni), palladium (Pd) and gold (Au) using the fourth photoresist layer 70 as a mask.

Referring now to FIG. 21, the patterned third and fourth photoresist layers 68 and 70 are removed. Exposed portions of the conductive film layer 26 are also removed, for example, by chemical etching.

As can be seen from FIG. 21, the conductive film layer 26 interfaces between the third conductive layer and the first insulating layer 20. The conductive film layer 26 provides the strong adhesion with the filler surface and hence the first insulating layer 20. Consequently, the die pad 28 and/or the conductive traces 32 also adhere well to the first insulating layer 20, thus reducing delamination concerns between the third conductive layer and the first insulating layer 20 during subsequent processes or applications and increasing the reliability of the resultant package.

As shown in FIG. 21, the substrate 10 thus formed includes a carrier 12 and a plurality of external pads 14 formed on the carrier 12, the external pads 14 formed on the carrier 12 defining a first conductive layer. A plurality of microvias 56 is formed on the external pads 14, the microvias 56 defining a second conductive layer. A first insulating layer 20 is formed on the carrier 12 with a molding compound 22. The first and second conductive layers are embedded in the first insulating layer 20. A conductive film layer 26 is formed over the second conductive layer and at least partially over the first insulating layer 20. A die pad 28, a plurality of bond pads 30 and a plurality of conductive traces 32 are formed on the second conductive layer and define a third conductive layer. The microvias 56 electrically connect the external pads 14 to the third conductive layer. In the embodiment shown, the substrate 10 also includes a first or bottom finishing layer 15 interfacing between the carrier 12 and the first conductive layer and a second or top finishing layer 34 formed on a surface of the third conductive layer.

In the present embodiment, the first conductive layer is defined by the external pads 14 and the second conductive layer is defined by the vertical posts or microvias 56. The first insulating layer 20 is formed on the carrier 12 and envelopes the first and second conductive layers. A top surface of the second conductive layer is completely exposed and is substantially leveled with the top surface of the first insulating layer 20. The third conductive layer is formed on the first insulating layer 20. The third conductive layer is electrically connected to the first conductive layer via the second conductive layer and extends above and overlaps the first insulating layer 20. The third conductive layer defines the wiring traces for forming the circuitry of the substrate 10.

In the present embodiment, the substrate also includes the conductive film layer 26 interfacing between the second and third conductive layers and between the first insulating layer 20 and the third conductive layer. The bottom finishing layer 15 interfaces between the first conductive layer and the carrier 12 and the top finishing layer 34 is formed on the top surface of the third conductive layer.

Advantageously, because microvias 56 are of smaller diameter than the dimensions of the external pads 14, density of the conductive traces 32 and thus connectivity can be increased by providing microvias 56 to access the external pads.

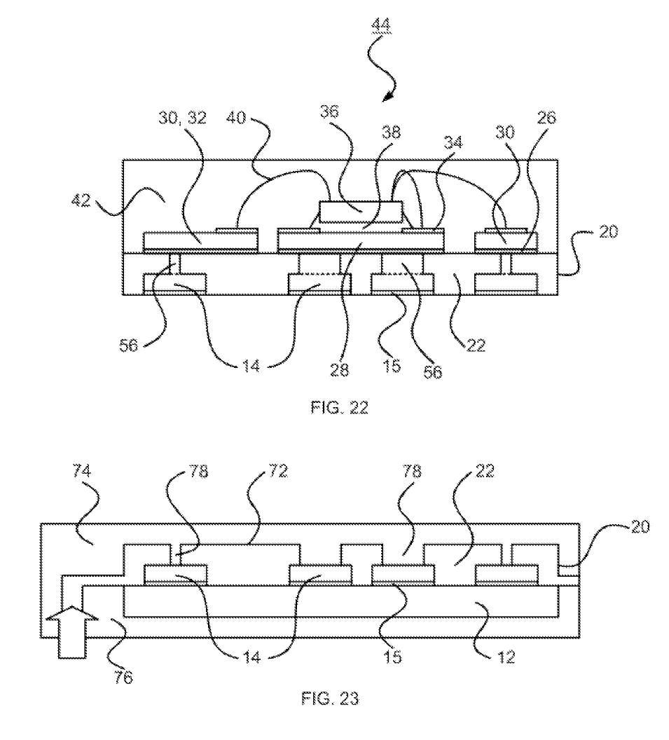

Referring now to FIG. 22, a semiconductor package 44 formed with the substrate of FIG. 21 is shown. The semiconductor package 44 includes a plurality of external pads 14 defining a first conductive layer. A plurality of microvias 56 is formed on the external pads 14, the microvias 56 defining a second conductive layer. The first and second conductive layers are embedded in a first insulating layer 20 formed with a molding compound 22. A conductive film layer 26 is formed over the second conductive layer and at least partially over the first insulating layer 20. A die pad 28, a plurality of bond pads 30 and a plurality of conductive traces 32 are formed on the second conductive layer and define a third conductive layer. The microvias 56 electrically connect the external pads 14 to the third conductive layer. A top finishing layer 34 is formed on a surface of the third conductive layer. A semiconductor chip 36 is attached to the die pad 28 and a plurality of wires 40 electrically connects the semiconductor chip 36 to the bond pads 30. An encapsulant 42 encapsulates the semiconductor chip 36, the wires 40 and the bond pads 30. In the embodiment shown, a bottom finishing layer 15 is formed on an underside of the external pads 14. In alternative embodiments, the semiconductor chip 36 may be flipchip-attached on the substrate 10.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

Following from FIG. 15 and with further reference to FIGS. 23 through 27, a further embodiment of the method of forming the substrate 10 for semiconductor packaging will now be described below.

Referring now to FIG. 23, the first photoresist layer 16 is removed after formation of the external pads 14 defining the first conductive layer on the carrier 12. A molding operation is then performed to form a first insulating layer 20 on the carrier 12 with a molding compound 22 by placing the carrier 12 with the first conductive layer formed thereon in a mold cavity 72 defined by a first mold part 74 and a second mold part 76. As can be seen from FIG. 23, the mold tooling is provided with a protruding pattern 78 in the first mold part 74 and defines the mold cavity 72 when closed. The protruding pattern 78 may be formed by computer numerical control (CNC) milling when fabricating the first mold part 74. In an alternative embodiment, the protruding pattern 78 may be a center piece inserted between the first and second mold parts 74 and 76. The carrier 12 with the first conductive layer formed thereon is clamped between the first and second mold parts 74 and 76 in the mold cavity 72 with the protruding pattern 78 contacting the first conductive layer. The first conductive layer may be first planarized by mechanical grinding, buffing or stamping to achieve substantial evenness, thereby minimizing non-contact between the protruding pattern 78 and the first conductive layer. The molding compound 22 is injected into the mold cavity 72 in liquid or molten state at high temperature and pressure, the molding compound 22 conforming to the shape of the mold cavity 72 with the protruding pattern 72. The first conductive layer is embedded in the first insulating layer 20 when the molding compound 22 cures.

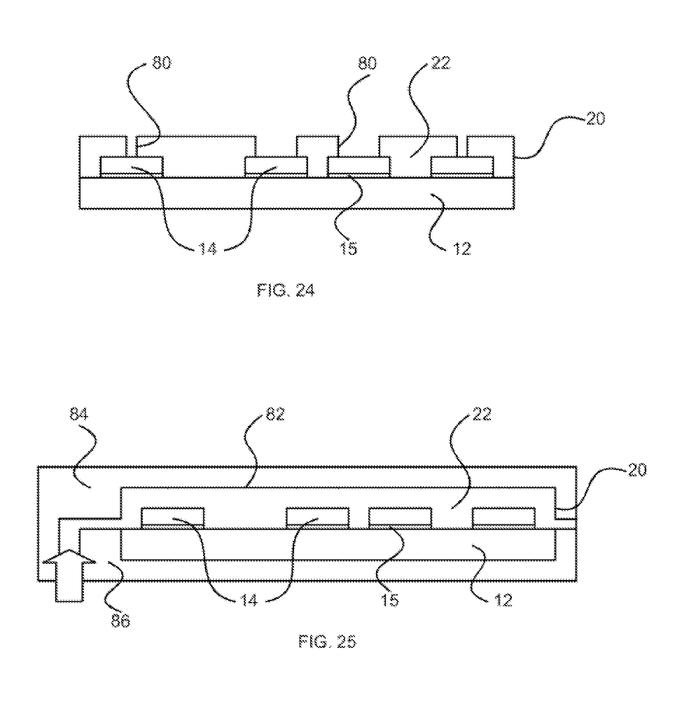

Referring now to FIG. 24, the carrier 12 with the first insulating layer 20 formed thereon is removed from the mold cavity 72 after the liquid molding compound 22 has been cured to a solid state to form a first dielectric or insulating layer 20 having a plurality of through-mold vias or microvia holes 80. The microvia holes 80 define the vertical studs 56 in the first insulating layer 20. The carrier 12 with the first insulating layer 20 formed thereon may be subjected to an extended duration of high temperature after removal from the mold cavity 72 to fully cure the molding compound 22.

As can be seen from FIGS. 23 and 24, a plurality of microvia holes 80 for the formation of the vertical studs or microvias 56 are formed in the first insulating layer 20 during the molding operation through the use of a mold part 74 having a protruding pattern 78 corresponding to an arrangement of the microvia holes 80 in the first insulating layer 20. In this manner, a first insulating layer 20 over the first conductive layer and at least one microvia hole 80 in the first insulating layer 20 exposing the first conductive layer may be simultaneously formed.

In an alternative embodiment, the protruding pattern 78 in the first mold part 74 may be provided for localized molding. Advantageously, this reduces the manufacturing cost due to cost savings from the reduction in materials used.

Although an injection molding process is shown in FIG. 23, it should be understood by those of ordinary skill in the art that the present invention is not limited by the type of molding process employed. For example, in an alternative embodiment, the first insulating layer 20 may be formed by a compression or transfer molding.

Referring now to FIG. 25, another method of forming the microvia holes 80 in the first insulating layer 20 will now be described. Following from FIG. 15, the first photoresist layer 16 is removed after formation of the external pads 14 defining the first conductive layer on the carrier 12. A molding operation is performed to form the first insulating layer 20 on the carrier 12 with a molding compound 22 by placing the carrier 12 with the first conductive layer formed thereon in a mold cavity 82 defined by a first mold part 84 and a second mold part 86. The molding compound 22 is injected into the mold cavity 82 in a liquid or molten state at high temperature and pressure, the molding compound 22 conforming to the shape of the mold cavity 82. The first conductive layer is embedded in the first insulating layer 20 when the molding compound 22 cures.

Referring again to FIG. 24, the carrier 12 with the first insulating layer 20 formed thereon is removed from the mold cavity 82 after the liquid molding compound 22 has been cured to a solid state and a plurality of microvia holes 80 for the formation of the microvias or vertical studs 56 are then formed in the first insulating layer 20 by one of laser drilling and mechanical drilling.

Referring now to FIG. 26, a conductive film layer 26 is formed over the first conductive layer and the first insulating layer 20 after the formation of the microvia holes 80. A second photoresist layer 52 is then formed over the conductive film layer 26 and patterned to expose the conductive film layer 26. A plurality of microvias 56, a die pad 28, a plurality of bond pads 30 and a plurality of conductive traces 32 are formed on the first conductive layer and define a second conductive layer. The second conductive layer is formed by electroplating on the conductive film layer 26 using the patterned second photoresist layer 52 as a mask.

As can be seen from FIG. 26, the second conductive layer fills the microvia holes 80 during the formation of the second conductive layer to form vertical studs 56 for connecting to the first conductive layer. The second conductive layer also defines the wiring traces 32 for forming the circuitry of the substrate 10. The second conductive layer may be formed by electroplating a single metal such as, for example, copper (Cu) or multiple metal layers such as, for example, combinations of copper (Cu), nickel (Ni), palladium (Pd) and gold (Au).

Alternatively, the microvia holes 80 may be filled with a conductive material prior to the formation of the second conductive layer on the first insulating layer 20. The conductive material may be injected or printed into the microvia holes 80. The conductive material may be a conductive paste such as, for example, tin (Sn) or silver (Ag) paste.

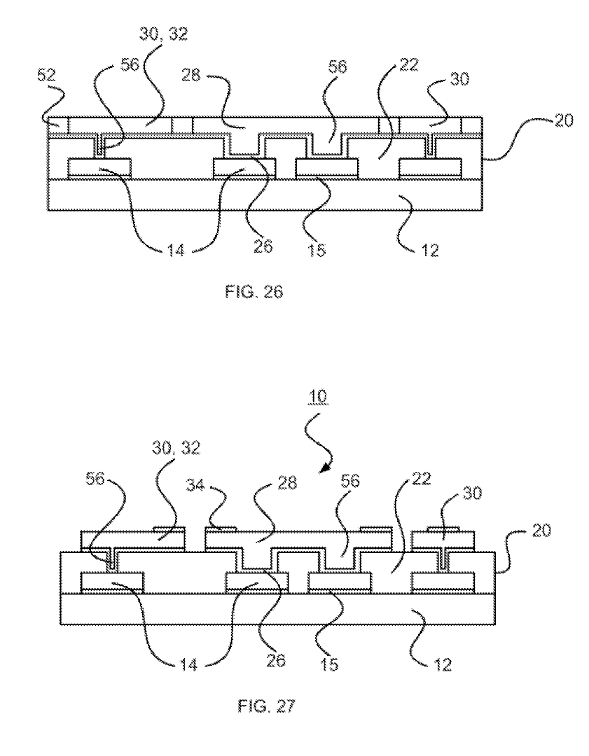

Referring now to FIG. 27, the patterned second photoresist layer 52 is removed and the exposed portions of the conductive film layer 26 are also removed, for example, by chemical etching. In the embodiment shown, a second or top finishing layer 34 is formed on selected surfaces of the second conductive layer by a photolithography process.

As shown in FIG. 27, the substrate 10 thus formed includes a carrier 12 and a plurality of external pads 14 formed on the carrier 12, the external pads 14 formed on the carrier 12 defining a first conductive layer. A first insulating layer 20 is formed on the carrier 12 with a molding compound 22 such that the first conductive layer is embedded in the first insulating layer 20. A conductive film layer 26 is formed over the first conductive layer and at least partially over the first insulating layer 20. A plurality of microvias 56, a die pad 28, a plurality of bond pads 30 and a plurality of conductive traces 32 are formed on the first conductive layer and define a second conductive layer. In the embodiment shown, the substrate 10 also includes a first or bottom finishing layer 15 interfacing between the carrier 12 and the first conductive layer and a second or top finishing layer 34 formed on a surface of the second conductive layer.

In the present embodiment, the second conductive layer is formed on the first conductive layer and the first insulating layer 20 and is electrically connected to the first conductive layer via the plurality of vertical studs 56. The second conductive layer extends above and overlaps the first insulating layer 20 and defines the wiring traces 32 for forming the circuitry of the substrate 10. The conductive film layer 26 of the present embodiment interfaces between the first and second conductive layers or between the first insulating layer 20 and the second conductive layer.

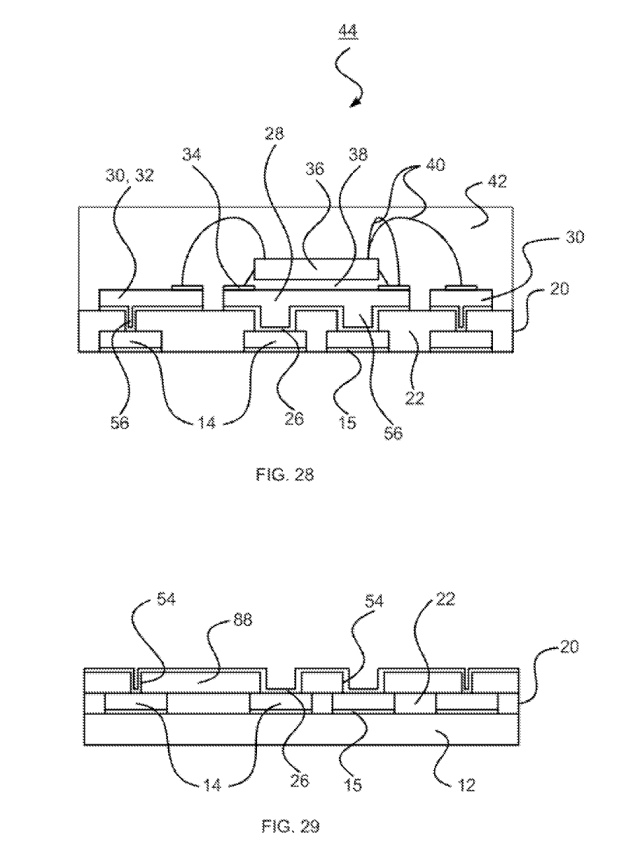

Referring now to FIG. 28, a semiconductor package 44 formed with the substrate of FIG. 27 is shown. The semiconductor package 44 includes a plurality of external pads 14 defining a first conductive layer. The first conductive layer is embedded in a first insulating layer 20 formed with a molding compound 22. A conductive film layer 26 is formed over the first conductive layer and at least partially over the first insulating layer 20. A plurality of microvias 56, a die pad 28, a plurality of bond pads 30 and a plurality of conductive traces 32 are formed on the first conductive layer and define a second conductive layer. A top finishing layer 34 is formed on a surface of the second conductive layer. A semiconductor chip 36 is attached to the die pad 28 and a plurality of wires 40 electrically connects the semiconductor chip 36 to the bond pads 30. An encapsulant 42 encapsulates the semiconductor chip 36, the wires 40 and the bond pads 30. In the embodiment shown, a bottom finishing layer 15 is formed on an underside of the external pads 14.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

FIGS. 29 through 31 are enlarged cross-sectional views illustrating a method of forming a substrate for semiconductor packaging in accordance with still another embodiment of the present invention.

Referring now to FIG. 29, a carrier 12 is provided and a plurality of external pads 14 is formed on the carrier, the external pads 14 formed on the carrier 12 define a first conductive layer. In the embodiment shown, a first or bottom finishing layer 15 is formed on the carrier 12 prior to formation of the external pads 14.

A molding operation is then performed to form a first insulating layer 20 on the carrier 12 with a molding compound 22. Consequent to the molding operation, the first conductive layer is embedded in the first insulating layer 20. A portion of the first insulating layer 20 is removed after the molding operation to expose a surface of the first conductive layer.

A second insulating layer 88 is formed over the first insulating layer 20 and the exposed surface of the first conductive layer. In the present embodiment, the second insulating layer 88 may be a solder mask, a molding compound, a woven fibreglass laminate or a primer. The second insulating layer 88 may be formed on the first conductive layer and the first insulating layer 20 by screen-printing, spin-coating or lamination. The first insulating layer 20 and the second insulating layer 88 may be formed of characteristically different materials. Preferably, the second insulating layer 88 is formed from a photo-imagable material.

A plurality of microvia holes 54 is formed in the second insulating layer 88 by one of photolithography, laser drilling and mechanical drilling. As can be seen from FIG. 29, the second insulating layer 88 is patterned to form a plurality of microvia holes 54.

A conductive seed layer 26 is formed over the second insulating layer 88 and the first conductive layer.

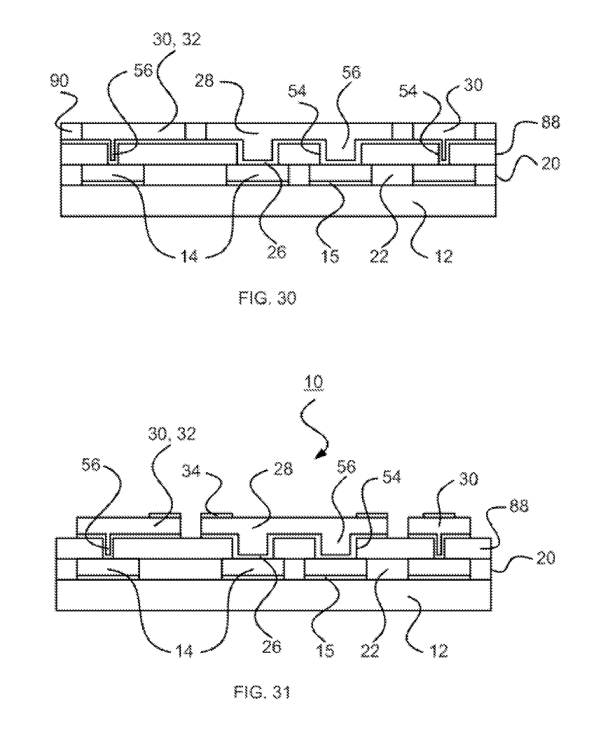

Referring now to FIG. 30, a photoresist layer 90 is formed over the conductive film layer 26 and patterned to expose the conductive film layer 26. A plurality of microvias 56, a die pad 28, a plurality of bond pads 30 and a plurality of conductive traces 32 are formed on the first conductive layer and define a second conductive layer. The second conductive layer is formed by electroplating on the conductive film layer 26 using the patterned photoresist layer 90 as a mask.

As can be seen from FIG. 30, during the formation of the second conductive layer, the second conductive layer also fills the microvia holes 54 to form vertical studs 56 for connecting to the first conductive layer. The second conductive layer also defines the wiring traces 32 for forming the circuitry of the substrate 10. The second conductive layer may be formed by electroplating a single metal such as, for example, copper (Cu) or multiple metal layers such as, for example, combinations of copper (Cu), nickel (Ni), palladium (Pd) and gold (Au).

Alternatively, the microvia holes 80 may be filled with a conductive material prior to the formation of the second conductive layer on the second insulating layer 88. The conductive material may be injected or printed into the microvia holes 80. The conductive material may be a conductive paste such as, for example, tin (Sn) or silver (Ag) paste.

Referring now to FIG. 31, the patterned photoresist layer 90 is removed and the exposed portions of the conductive film layer 26 are also removed, for example, by chemical etching. In the embodiment shown, a second or top finishing layer 34 is formed on selected surfaces of the second conductive layer by a photolithography process.

As shown in FIG. 27, the substrate 10 thus formed includes a carrier 12 and a plurality of external pads 14 formed on the carrier 12, the external pads 14 formed on the carrier 12 defining a first conductive layer. A first insulating layer 20 is formed on the carrier 12 with a molding compound 22 such that the first conductive layer is embedded in the first insulating layer 20. A second insulating layer 88 is formed over the first insulating layer 20 and a plurality of microvia holes 54 is formed in the second insulating layer 88, exposing a surface of the first conductive layer. A conductive film layer 26 is formed over the first conductive layer and at least partially over the second insulating layer 88. A plurality of microvias 56, a die pad 28, a plurality of bond pads 30 and a plurality of conductive traces 32 are formed on the first conductive layer and define a second conductive layer. In the embodiment shown, the substrate 10 also includes a first or bottom finishing layer 15 interfacing between the carrier 12 and the first conductive layer and a second or top finishing layer 34 formed on a surface of the second conductive layer.

In the present embodiment, the second insulating layer 88 is formed on the first insulating layer 20 and the first conductive layer and the second conductive layer is formed on the first conductive layer and the second insulating layer 88. The second conductive layer is electrically connected to the first conductive layer via the plurality of vertical studs 56 and extends above and overlaps the second insulating layer 88. The second conductive layer defines the wiring traces for forming the circuitry of the substrate 10. The conductive film layer 26 of the present embodiment interfaces between the first conductive layer and the vertical studs and between the second insulating layer 88 and the second conductive layer.

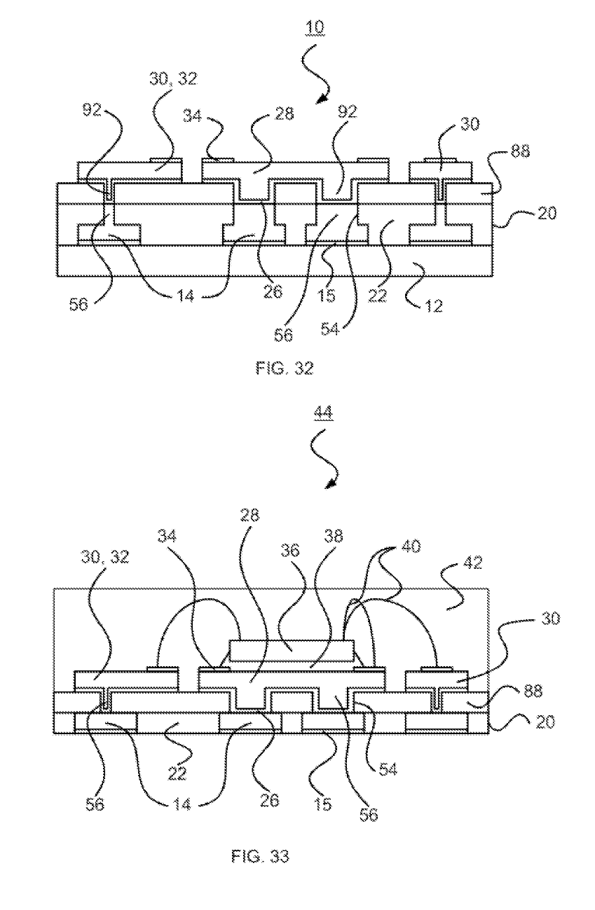

Referring now to FIG. 32, an enlarged cross-sectional view of a substrate 10 for semiconductor packaging in accordance with another embodiment of the present invention is shown. The substrate 10 includes a carrier 12 and a plurality of external pads 14 formed on the carrier 12, the external pads 14 formed on the carrier 12 defining a first conductive layer. A plurality of first microvias 56 is formed on the external pads 14, the microvias 56 defining a second conductive layer. A first insulating layer 20 is formed on the carrier 12 with a molding compound 22. The first and second conductive layers are embedded in the first insulating layer 20. A second insulating layer 88 is formed over the first insulating layer 20 and a plurality of microvia holes 54 is formed in the second insulating layer 88, exposing a surface of the first conductive layer. A conductive film layer 26 is formed over the second conductive layer and at least partially over the second insulating layer 88. A plurality of second microvias 92, a die pad 28, a plurality of bond pads 30 and a plurality of conductive traces 32 are formed on the second conductive layer and define a third conductive layer. The second microvias 92 are formed in the microvia holes 54 and interconnect the second conductive layer with the third conductive layer. In the embodiment shown, the substrate 10 also includes a first or bottom finishing layer 15 interfacing between the carrier 12 and the first conductive layer and a second or top finishing layer 34 formed on a surface of the third conductive layer.

As can be seen from FIG. 32, a second layer of microvias 92 is formed on a preceding conductive layer in the present embodiment.

Referring now to FIG. 33, a semiconductor package 44 formed with the substrate of FIG. 31 is shown. The semiconductor package 44 includes a plurality of external pads 14 defining a first conductive layer. The first conductive layer is embedded in a first insulating layer 20 formed with a molding compound 22. A second insulating layer 88 is formed over the first insulating layer 20 and a plurality of microvia holes 54 is formed in the second insulating layer 88, exposing a surface of the first conductive layer. A conductive film layer 26 is formed over the first conductive layer and at least partially over the second insulating layer 88. A plurality of microvias 56, a die pad 28, a plurality of bond pads 30 and a plurality of conductive traces 32 are formed on the first conductive layer and define a second conductive layer. A top finishing layer 34 is formed on a surface of the second conductive layer. A semiconductor chip 36 is attached to the die pad 28 and a plurality of wires 40 electrically connects the semiconductor chip 36 to the bond pads 30. An encapsulant 42 encapsulates the semiconductor chip 36, the wires 40 and the bond pads 30. In the embodiment shown, a bottom finishing layer 15 is formed on an underside of the external pads 14.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

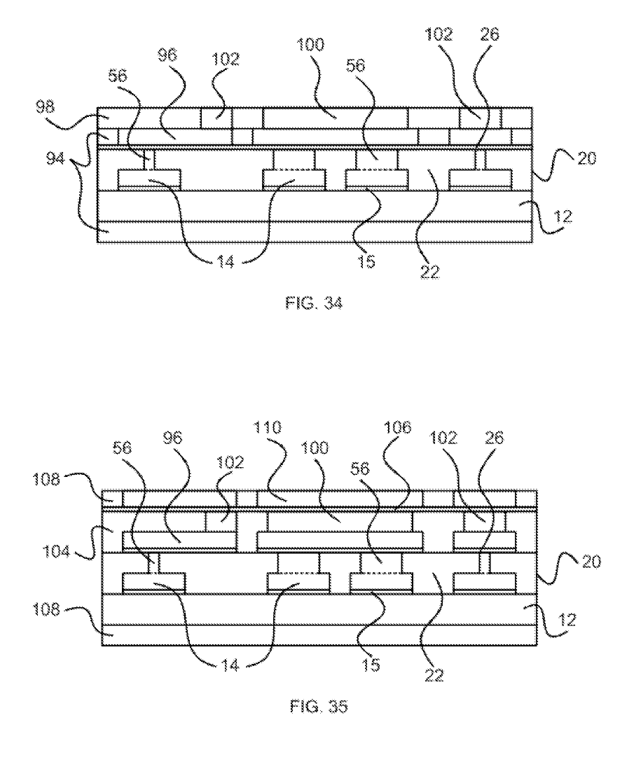

Following from FIG. 19 and with further reference to FIGS. 34 through 36, a further embodiment of the method of forming the substrate 10 for semiconductor packaging will now be described below.

Referring now to FIG. 34, a first photoresist layer 94 is formed on a first conductive film layer 26 after the first conductive film layer 26 is formed on the second conductive layer and the first insulating layer 20 that are formed on the carrier 12. The first photoresist layer 94 is then patterned to expose the first conductive film layer 26. A third conductive layer 96 is formed by electroplating on the first conductive film layer 26 using the patterned first photoresist layer 94 as a mask. The third conductive layer 96 defines a plurality of first wiring traces and may be formed of a single metal such as, for example, copper (Cu) or multiple metal layers such as, for example, combinations of copper (Cu), nickel (Ni), palladium (Pd) and gold (Au).

A second photoresist layer 98 is then formed on the first photoresist layer 94 and the third conductive layer 96 and patterned to expose the third conductive layer 96. A fourth conductive layer 100 is formed by electroplating on the third conductive layer 96 using the patterned second photoresist layer 98 as a mask. The fourth conductive layer 100 defines a plurality of second microvias or vertical posts 102 and may be formed of a single metal such as, for example, copper (Cu) or multiple metal layers such as, for example, combinations of copper (Cu), nickel (Ni), palladium (Pd) and gold (Au).

Referring now to FIG. 35, the first and second photoresist layers 94 and 98 are removed after the second microvias 102 are formed on the third conductive layer 96. Exposed portions of the first conductive film layer 26 are also removed, for example, by chemical etching.

A second insulating layer 104 is formed over the first insulating layer. In the present embodiment, the second insulating layer 104 is made of a molding compound material. Similar to the first insulating layer 20, an injection or a compression molding process may be employed to form the second insulating layer 104 to encapsulate the third and fourth conductive layers 96 and 100. A mechanical grinding or buffing process may be employed to remove a portion of the second insulating layer 104 to expose a surface of the fourth conductive layer 100 after the molding operation. Preferably, the first and second insulating layers 20 and 104 are made of the same molding compound material.

A second conductive film layer 106 is formed over the second insulating layer 104 and the fourth conductive layer 100. The second conductive film layer 106 may be made of copper (Cu) and may be formed by an electroless process.

A third photoresist layer 108 is then formed on the second conductive film layer 106 and patterned to expose the second conductive film layer 106. A fifth conductive layer 110 is formed by electroplating on the second conductive film layer 106 using the patterned third photoresist layer 108 as a mask. The fifth conductive layer 110 defines a plurality of second wiring traces and may be formed of a single metal such as, for example, copper (Cu) or multiple metal layers such as, for example, combinations of copper (Cu), nickel (Ni), palladium (Pd) and gold (Au).

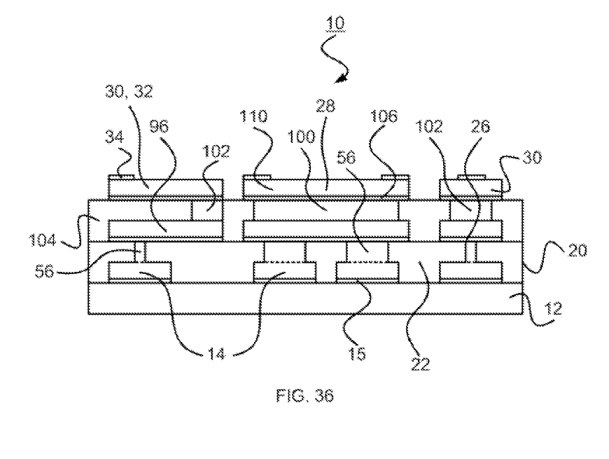

Referring now to FIG. 36, the third photoresist layer 108 is removed and exposed portions of the second conductive film layer 106 are also removed, for example, by chemical etching. In the embodiment shown, a second or top finishing layer 34 is formed on selected surfaces of the fifth conductive layer 110 by a photolithography process.

As shown in FIG. 36, the substrate 10 thus formed includes a carrier 12 and a plurality of external pads 14 formed on the carrier 12, the external pads 14 formed on the carrier 12 defining a first conductive layer. A plurality of first microvias 56 is formed on the external pads 14, the first microvias 56 defining a second conductive layer. A first insulating layer 20 is formed on the carrier 12 with a molding compound 22, the first insulating layer 20 enveloping the first and second conductive layers. A first conductive film layer 26 is formed over the second conductive layer and at least partially over the first insulating layer 20. A third conductive layer 96 is formed on the second conductive layer and the first insulating layer 20 and a fourth conductive layer 100 is formed on the third conductive layer 96. A second insulating layer 104 is formed over the first insulating layer 20 and envelopes the third and fourth conductive layers 96 and 100. A second conductive film layer 106 is formed over the fourth conductive layer 100 and at least partially over the second insulating layer 104. A die pad 28, a plurality of bond pads 30 and a plurality of conductive traces 32 are formed on the fourth conductive layer 100 and define a fifth conductive layer 110. In the embodiment shown, the substrate 10 also includes a first or bottom finishing layer 15 interfacing between the carrier 12 and the first conductive layer and a second or top finishing layer 34 formed on a surface of the fifth conductive layer 110.

In the present embodiment, the third conductive layer 96 is electrically connected to the second conductive layer via the plurality of first microvias 56 and extends above and overlaps the first insulating layer 20. In the present embodiment, the third conductive layer 96 defines the first wiring traces for forming the circuitry of the substrate 10 and the fourth conductive layer 100 defines a plurality of second microvias or vertical posts. In the present embodiment, a top surface of the fourth conductive layer 100 is completely exposed and is substantially leveled with a top surface of the second insulating layer 104. In the present embodiment, the fifth conductive layer 110 is formed on the fourth conductive layer 100 and the second insulating layer 104. The fifth conductive layer 110 is electrically connected to the fourth conductive layer 100 via the plurality of second microvias 92 and extends above and overlaps the second insulating layer 104. The fifth conductive layer 110 defines the second wiring traces for forming the circuitry of the substrate 10.

In the present embodiment, the first conductive film layer 26 interfaces between the second and third conductive layers and between the first insulating layer 20 and the third conductive layer 96. In the present embodiment, the second conductive film layer 104 interfaces between the fourth and fifth conductive layers 100 and 110 and between the second insulating layer 104 and the fifth conductive layer 110.

As will be understood by those of ordinary skill in the art, the various steps described may be repeated in alternative embodiments to form a multi-layer build-up substrate that may be finished by forming a top finishing layer on the final or uppermost conductive layer.

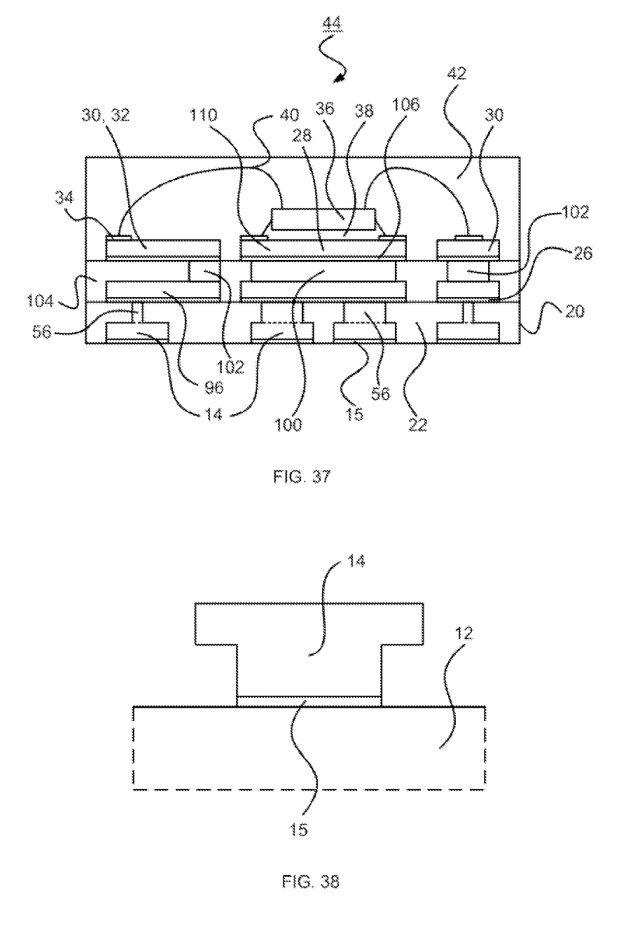

Referring now to FIG. 37, a semiconductor package 44 formed with the substrate of FIG. 36 is shown. The semiconductor package 44 includes a plurality of external pads 14 defining a first conductive layer. A plurality of microvias 56 is formed on the external pads 14, the microvias 56 defining a second conductive layer. The first and second conductive layers are embedded in a first insulating layer 20 formed with a molding compound 22. A first conductive film layer 26 is formed over the second conductive layer and at least partially over the first insulating layer 20. A third conductive layer 96 is formed on the second conductive layer and the first insulating layer 20 and a fourth conductive layer 100 is formed on the third conductive layer 96. A second insulating layer 104 is formed over the first insulating layer 20 and envelopes the third and fourth conductive layers 96 and 100. A second conductive film layer 106 is formed over the fourth conductive layer 100 and at least partially over the second insulating layer 104. A die pad 28, a plurality of bond pads 30 and a plurality of conductive traces 32 are formed on the fourth conductive layer 100 and define a fifth conductive layer 110. A top finishing layer 34 is formed on a surface of the fifth conductive layer 110. A semiconductor chip 36 is attached to the die pad 28 and a plurality of wires 40 electrically connects the semiconductor chip 36 to the bond pads 30. An encapsulant 42 encapsulates the semiconductor chip 36, the wires 40 and the bond pads 30. In the embodiment shown, a bottom finishing layer 15 is formed on an underside of the external pads 14.

The encapsulant 42 may be of the same material or molding compound as that used to form the dielectric or insulating layer of the substrate 10. Advantageously, this helps to reduce or prevent stresses to the semiconductor package 44 resulting from a mismatch of material properties.

Referring now to FIG. 38, in an alternative to the embodiments described above, the method of forming the substrate 10 for semiconductor packaging may include stamping or coining the first conductive layer to create a rivet head profile shown in FIG. 38 on the external pads 14 prior to performing the molding operation. In such an embodiment, the external pads 14 defining the first conductive layer of the substrate 10 and the semiconductor package 44 have a rivet head profile as shown in FIG. 38. Advantageously, this helps prevent disengagement of the external pads 14 from the first insulating layer 20 and improves the reliability of the semiconductor package 44.

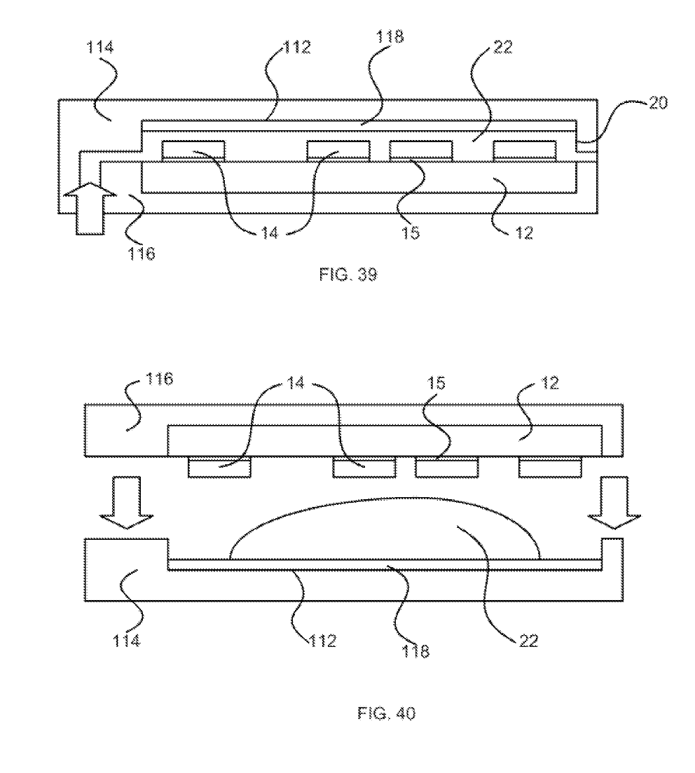

Although the conductive traces and the conductive film layer are described as being formed by electroplating and an electroless process, respectively, in the preceding embodiments, it should be understood by those of ordinary skill in the art that the present invention is not limited to these methods and alternative methods of forming the conductive traces and the conductive film layer will now be described below with reference to FIGS. 39 through 44.

Referring now to FIG. 39, a carrier 12 with a first conductive layer 14 formed thereon is placed in a mold cavity 112 defined by a first mold part 114 and a second mold part 116 as shown. In another embodiment, a carrier 12 with a first conductive layer 14 and a plurality of vertical studs 56 formed thereon as seen in FIG. 17, may be used. As can be seen from FIG. 39, the first mold part 114 is lined with a metallic foil 118.

The carrier 12 and the metallic foil 118 may be held in place by vacuum, electrostatic attraction, magnetic attraction or other appropriate means. In the present embodiment, the metallic foil 118 has a thickness of less than about 30 microns (μm). The metallic foil 118 may be a copper (Cu) foil. The mold tooling may be preheated.

In the embodiment shown, the carrier 12 and the metallic foil 118 are completely enclosed in the mold cavity 112 when the first and second mold parts 114 and 116 are clamped together. In the present embodiment, a gap is provided between the first conductive layer 14 (or the vertical studs 56) and the metallic foil 118 in the mold cavity 112. Prior to placement in the mold cavity, the first conductive layer 14 (or the vertical studs 56) may be stamped or coined to achieve an even height in order to achieve a consistent gap. The gap is preferably of less than about 30 microns (μm).

A liquid molding compound 22 is injected into the mold cavity 112 at high pressure. The molding compound 22 may be preheated from a solid state to a liquid state at high temperature prior to injecting into the mold cavity 112. The liquid molding compound 22 fills the mold cavity 112, connects the carrier 12 to the metallic foil 118 and encapsulates the first conductive layer 14. The metallic foil 118 may also be encapsulated if its dimension is less than that of the mold cavity 112. The molding compound 22 partially cures and solidifies over an extended duration of high temperature to form a first dielectric layer 20. In the process, the molding compound 22 adheres and bonds with the metallic foil 118. In this manner, the metallic foil 118 adheres to the first dielectric layer 20 22 upon curing of the molding compound 22. The metallic foil 118 may be chemically or mechanically treated to roughen the surface prior to placement into the mold cavity 112 to improve adhesion to the first dielectric layer 20.

Referring now to FIG. 40, as an alternative to injection or transfer molding, compression molding is shown in FIG. 40 and will now be described below.

A carrier 12 with a first conductive layer 14 formed thereon is placed in a mold cavity 112 defined by a first mold part 114 and a second mold part 116. In another embodiment, a carrier 12 with a first conductive layer 14 and a plurality of vertical studs 56 formed thereon as seen in FIG. 17, may be used. The first mold part 114 is lined with a metallic foil 118. The mold tooling may be preheated.

A molding compound 22 is placed onto the metallic foil 118 (or onto the carrier 12) and the first and second mold parts 114 and 116 are clamped together to compress the carrier 12 (or metallic foil 118) onto the molding compound 22 at high pressure and high temperature. The molding compound 22 may be in a paste or fluid form. Alternatively, the molding compound is in a solid or powdered form and heated to melt it to a liquid state to encapsulate the first conductive layer 114 and fill the mold cavity 112 completely. The liquid molding compound 22 cures and solidifies over an extended duration of high temperature to form a first dielectric layer 20. In the process, the metallic foil 118 bonds with the first dielectric layer 20 upon curing of the molding compound to form a conductive film layer 118.

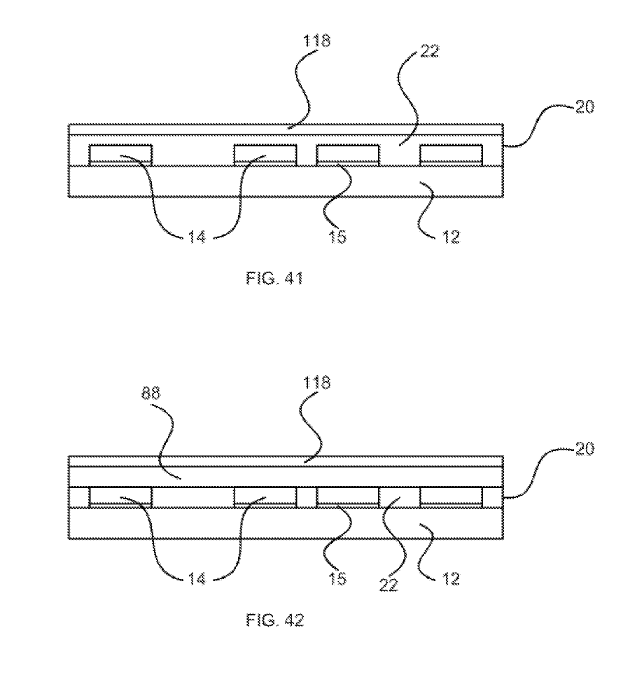

Referring now to FIG. 41, the carrier 12 is removed from the mold tooling. A first dielectric layer 20 on the carrier 12 and encapsulating the first conductive layer 14 (and the vertical studs 56) and a first conductive film layer or trace 118 on the first dielectric layer 20 are simultaneously formed. The assembly may be subjected to further high temperature treatment to fully cure the molding compound 22 and strengthen the bond with the metallic layer 118

Advantageously, the described method of forming the conductive trace and the conductive film layer on the molding compound 22 improves adhesion of the conductive trace and the conductive film layer to the first dielectric layer 20.

Referring now to FIG. 42, the described method may similarly be used to form a conductive trace or a conductive film layer 118 on a second insulating layer 88 as shown in FIG. 42.

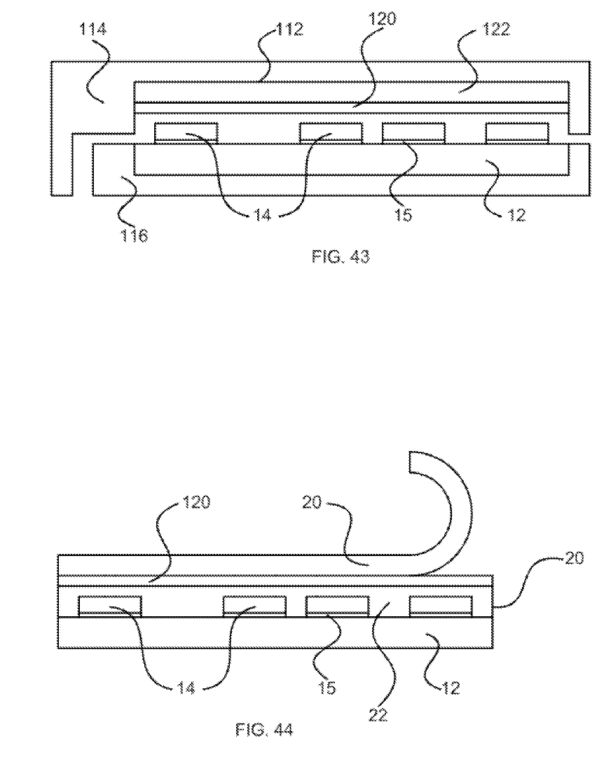

Referring now to FIG. 43, as an alternative to the metallic foil 118, a metallic layer 120 provided on a support layer 122 may be used as shown in FIGS. 43 and 44 in an alternative embodiment. The metallic layer 120 may be formed on the support layer 122 by electroplating or sputtering. The support layer 122 may be an epoxy tape. Advantageously, with this embodiment, a thin metallic layer is achievable without the need for post-thinning of the metallic foil. Further advantageously, with a thin metallic layer, the surface roughness of the metallic layer 120 follows that of the support layer 122 and thus surface roughness of the metallic layer 120 may be controlled by selecting a support layer with the desired roughness without additional processing steps required. The roughening effect helps improve adhesion of the metallic layer 120 to the first dielectric layer 20.

A titanium (Ti) layer may be formed on the support layer 122 prior to forming the metallic layer 120 to act as a conducting plane for electroplating copper and non-bondable to copper.

Referring now to FIG. 44, after forming the first dielectric layer 20, the support layer 122 may be peeled off, leaving the metallic layer 120 on the first dielectric layer 20 as the conductive film layer 120.

As is evident from the foregoing discussion, the present invention provides a substrate for semiconductor packaging, a method of forming the substrate, a method of packaging a semiconductor chip with the substrate and a panel-based, low cost semiconductor package. Advantageously, large panel processing producing multiple package units per panel is possible with the substrate of the present invention. This reduces the manufacturing cost per semiconductor package. In embodiments where the insulating layer is formed of the same material as the encapsulant, a more reliable package is formed as the substrate body will then have the same coefficient of thermal expansion as the encapsulant and this helps prevent separation of the encapsulant from the underlying dielectric layer.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiments disclosed, but covers modifications within the scope of the present invention as defined by the appended claims.

Further, unless the context clearly requires otherwise, throughout the description and the claims, the words “comprise”, “comprising” and the like are to be construed in an inclusive as opposed to an exclusive or exhaustive sense; that is to say, in the sense of “including, but not limited to”.

1. A method of forming a substrate for semiconductor packaging, the method comprising:
providing a carrier;
forming a plurality of external pads on the carrier, the external pads formed on the carrier defining a first conductive layer;
performing a molding operation to form a first insulating layer on the carrier with a molding compound, wherein the first conductive layer is embedded in the first insulating layer; and
forming one or more of a plurality of bond pads, a plurality of conductive traces and a plurality of microvias on the first conductive layer, the one or more of the bond pads, the conductive traces and the microvias formed on the first conductive layer defining a second conductive layer.

2. The method of claim 1, wherein the step of forming the first conductive layer on the carrier comprises:
forming a photoresist layer on the carrier;
patterning the photoresist layer to form a plurality of openings in the photoresist layer;
depositing one or more metal layers in the openings formed in the photoresist layer to form the first conductive layer; and
removing the photoresist layer.

3. The method of claim 1, wherein the molding compound comprises a resin and one or more fillers.

4. The method of claim 3, wherein the molding compound comprises between about 70 weight percent and about 95 weight percent of the one or more fillers.

5. The method of claim 3, wherein the molding compound has a coefficient of thermal expansion of between about 5 and about 15 parts per million per degree Celsius (ppm/° C.).

6. The method of claim 1, wherein a plurality of first microvias is formed on the external pads, the first microvias defining the second conductive layer, wherein one or more of the bond pads and a plurality of first conductive traces are formed on the second conductive layer and define a third conductive layer, and wherein the first microvias electrically connect the external pads to the third conductive layer.

7. The method of claim 6, wherein the first microvias are formed on the external pads prior to performing the molding operation to form the first insulating layer on the carrier and wherein the first microvias are embedded in the first insulating layer after the molding operation.

8. The method of claim 6, wherein a plurality of microvia holes for the first microvias are formed in the first insulating layer during the molding operation through the use of a mold part having a protruding pattern corresponding to an arrangement of the microvia holes in the first insulating layer.

9. The method of claim 6, further comprising forming a plurality of microvia holes for the first microvias in the first insulating layer by one of laser drilling and mechanical drilling.

10. The method of claim 6, further comprising forming a layer of microvias on a preceding conductive layer.

11. The method of claim 1, further comprising forming one or more successive insulating layers over the first insulating layer, the one or more successive insulating layers comprising one or more of a solder mask, a molding compound, a woven fibreglass laminate, a primer, a resin-coated copper (RCC) film, and a prepreg or woven glass laminate with a metallic foil.

12. The method of claim 11, further comprising forming a plurality of microvia holes in one of the one or more successive insulating layers by one of photolithography, laser drilling and mechanical drilling.

13. The method of claim 11, further comprising forming a conductive film layer over one or more of the first insulating layer, the one or more successive insulating layers and a conductive layer prior to forming one or more of the bond pads and the conductive traces over the conductive layer.

14. The method of claim 13, further comprising one or both of:
roughening a surface of the first or successive insulating layer and/or the conductive layer prior to forming the conductive film layer; and
chemically activating a plurality of surface bonds of the first or successive insulating layer prior to forming the conductive film layer.

15. The method of claim 1, wherein the molding operation comprises:
placing the carrier with the first conductive layer formed thereon in a mold cavity defined by a first mold part and a second mold part;
packing the mold cavity with the molding compound in a liquid or molten state by injection or compression;
curing the molding compound to form the first insulating layer on the carrier.

16. The method of claim 15, further comprising lining the first mold part with a metallic foil, wherein the metallic foil adheres to the molding compound upon curing of the molding compound.

17. The method of claim 16, wherein the metallic foil has a thickness of less than about 30 microns (μm).

18. The method of claim 16, wherein the metallic foil is provided on a support layer.

19. The method of claim 1, further comprising:
removing a portion of the first insulating layer after the molding operation to expose a surface of an underlying conductive layer.

20. The method of claim 1, further comprising:
stamping the first conductive layer to create a rivet head profile on the external pads prior to performing the molding operation.

21. A substrate for semiconductor packaging, the substrate comprising:
a carrier;
a plurality of external pads formed on the carrier, the external pads formed on the carrier defining a first conductive layer;
a first insulating layer formed on the carrier with a molding compound, wherein the first conductive layer is embedded in the first insulating layer; and
one or more of a plurality of bond pads, a plurality of conductive traces and a plurality of microvias formed on the first conductive layer, the one or more of the bond pads, the conductive traces and the microvias formed on the first conductive layer defining a second conductive layer.

22. The substrate of claim 21, wherein the molding compound comprises a resin and one or more fillers.

23. The substrate of claim 22, wherein the molding compound comprises between about 70 weight percent and about 95 weight percent of the one or more fillers.

24. The substrate of claim 22, wherein the molding compound has a coefficient of thermal expansion of between about 5 and about 15 parts per million per degree Celsius (ppm/° C.).

25. The substrate of claim 21, wherein a plurality of first microvias is formed on the external pads, the first microvias defining the second conductive layer, wherein one or more of the bond pads and a plurality of first conductive traces are formed on the second conductive layer and define a third conductive layer, and wherein the first microvias electrically connect the external pads to the third conductive layer.

26. The substrate of claim 25, further comprising a layer of microvias formed on a preceding conductive layer.

27. The substrate of claim 21, further comprising one or more successive insulating layers formed over the first insulating layer, the one or more successive insulating layers comprising one or more of a solder mask material, a molding compound material, a woven glass laminate, a primer, a resin-coated copper (RCC) film, and a prepreg or woven glass laminate with a metallic foil.

28. The substrate of claim 27, further comprising a conductive film layer formed at least partially over one or more of the first insulating layer, the one or more successive insulating layers and a conductive layer.

29. The substrate of claim 21, wherein the external pads defining the first conductive layer have a rivet head profile.

30. A method of packaging a semiconductor chip, comprising:
providing a substrate for semiconductor packaging formed in accordance with the method of claim 1;
attaching the semiconductor chip to one of the external pads and a die pad of the substrate;
electrically connecting the semiconductor chip to the bond pads of the substrate with a plurality of wires;
encapsulating the semiconductor chip, the wires and the bond pads with an encapsulant; and
removing the carrier to expose the first conductive layer.

31. A semiconductor package, comprising:
a plurality of external pads, the external pads defining a first conductive layer;
a first insulating layer formed with a molding compound, wherein the first conductive layer is embedded in the first insulating layer;
one or more of a die pad, a plurality of bond pads, a plurality of conductive traces and a plurality of microvias formed on the first conductive layer, the one or more of the die pad, the bond pads, the conductive traces and the microvias formed on the first conductive layer defining a second conductive layer;
a semiconductor chip attached to one of the external pads and the die pad;
a plurality of wires electrically connecting the semiconductor chip to the bond pads; and
an encapsulant encapsulating the semiconductor chip, the wires and the bond pads.

32. The semiconductor package of claim 31, wherein the molding compound comprises a resin and one or more fillers.

33. The semiconductor package of claim 32, wherein the molding compound comprises between about 70 weight percent and about 95 weight percent of the one or more fillers.

34. The semiconductor package of claim 32, wherein the molding compound has a coefficient of thermal expansion of between about 5 and about 15 parts per million per degree Celsius (ppm/° C.).

35. The semiconductor package of claim 31, wherein a plurality of first microvias is formed on the external pads, the first microvias defining the second conductive layer, wherein one or more of the bond pads and a plurality of first conductive traces are formed on the second conductive layer and define a third conductive layer, and wherein the first microvias electrically connect the external pads to the third conductive layer.

36. The semiconductor package of claim 35, further comprising a layer of microvias formed on a preceding conductive layer.

37. The semiconductor package of claim 31, further comprising one or more successive insulating layers formed over the first insulating layer, the one or more successive insulating layers comprising one or more of a solder mask material, a molding compound material, a woven glass laminate, a primer, a resin-coated copper (RCC) film, and a prepreg or woven glass laminate with a metallic foil.

38. The semiconductor package of claim 37, further comprising a conductive film layer formed at least partially over one or more of the first insulating layer, the one or more successive insulating layers and a conductive layer.

39. The semiconductor package of claim 31, wherein the external pads defining the first conductive layer have a rivet head profile.
